(19) United States
(12) Patent Application Publication
(10) Pub. No.: US 2026/0146970 A1
(43) Pub. Date: May 28, 2026

(54) SINGLE TRANSISTOR SENSING DEVICE AND OPERATING METHOD THEREOF

(71) Applicant: CHANG GUNG UNIVERSITY, Taoyuan City (TW)

(72) Inventors: CHAO-SUNG LAI, Taoyuan City (TW); CHIA-MING YANG, New Taipei City (TW); FUAD UGHI, Tangerang County (ID)

(21) Appl. No.: 19/230,059

(22) Filed: Jun. 5, 2025

(30) Foreign Application Priority Data
Nov. 22, 2024 (TW) 113145144

(51) Int. Cl. G01N 27/414; G01N 27/416; G01N 27/48; H10D 84/80

(52) U.S. Cl. CPC G01N 27/414; G01N 27/4167; G01N 27/48; H10D 84/813

(57) ABSTRACT

A single transistor sensing device includes a transistor, an extended gate, a tank, a reference electrode and an analysis device. The gate of the transistor connects to the extended gate. The tank is deposed in solution. The extended gate and the reference electrode are in the solution and operating specific electrical condition. The single transistor sensing device can break the Nernst limit and amplify sensitivity.

### TECHNICAL FIELD

The present invention relates to a single transistor sensing device, especially for a single transistor sensing device and operating method can break the Nernst limit.

### BACKGROUND OF RELATED ARTS

The ideal pH sensitivity which is called Nernst limit is 59.6 mV/pH for a normal pH sensor. Surface bonding site model and Nernst equation are defined as the largest pH sensitivity.

The methods of breaking the pH sensitivity Nernst limit are using specific electric circuit design to amplify signal or using specific field-effect sensing component design and material, such as adjusting size of sensing gate and coupling effect, nanostructure and two-dimensional material, double gate and multi-gate, etc. Defects of these methods are complex component structure, process and extra cost.

### SUMMARY

Therefore, the purpose of the present invention is to provide a single transistor sensing device and operating method thereof.

The single transistor sensing device of present invention includes a transistor, an extended gate, a tank, a reference electrode and an analysis device.

The transistor includes a source, a drain, a body, a gate and an oxide layer. The extended gate includes a substrate and a sensing layer.

Further, an operating method of the single transistor sensing device of the present invention includes the following steps. First, the step (A) is providing the single transistor sensing device. The step (B) is preparing a test solution in the tank. The step (C) is immersing the reference electrode in the test solution.

Moreover, the step (D) is inputting a first fixed voltage into the reference electrode. The step (E) is grounding the source. The step (F) is inputting a second fixed voltage into the drain. The step (G) is inputting a variable voltage into the body. The step (H) is the analysis device measuring a current which is from the drain to the source. The step (I) is acquiring a curve via taking absolute value of current versus the variable voltage. The step (J) is calculating a pH sensitivity via taking pH of the test solution versus the variable voltage.

The present invention is the operating method of the single transistor sensing device can break pH sensitivity of Nernst limit.

### BRIEF DESCRIPTION OF THE DRAWINGS

FIG. 1 shows a diagram of the single transistor sensing device of an embodiment of the present invention.

FIG. 2 shows a diagram of the extended gate of the embodiment of the present invention.

FIG. 3 shows a diagram of the single transistor sensing device of the embodiment of the present invention.

FIG. 4 shows a framework diagram of the single transistor sensing device of an embodiment of the present invention.

FIG. 5 illustrates a flow chart of the single transistor sensing device and operating method of an embodiment of the present invention.

FIG. 6 shows a characteristic diagram of the single transistor sensing device of an embodiment of the present invention.

FIG. 7 shows a sensitivity diagram of the single transistor sensing device of an embodiment of the present invention.

### DETAILED DESCRIPTION OF THE INVENTION

In order to understand the technical features and practical efficacy of the present invention and to implement the technical features and practical efficacy in accordance with the contents of the specification, hereinafter, preferred embodiments of the present invention will be described in detail with reference to the accompanying drawings.

One embodiment of the single transistor sensing device of the present invention includes a transistor 10, an extended gate 40, a tank 50, a reference electrode 60 and an analysis device 70.

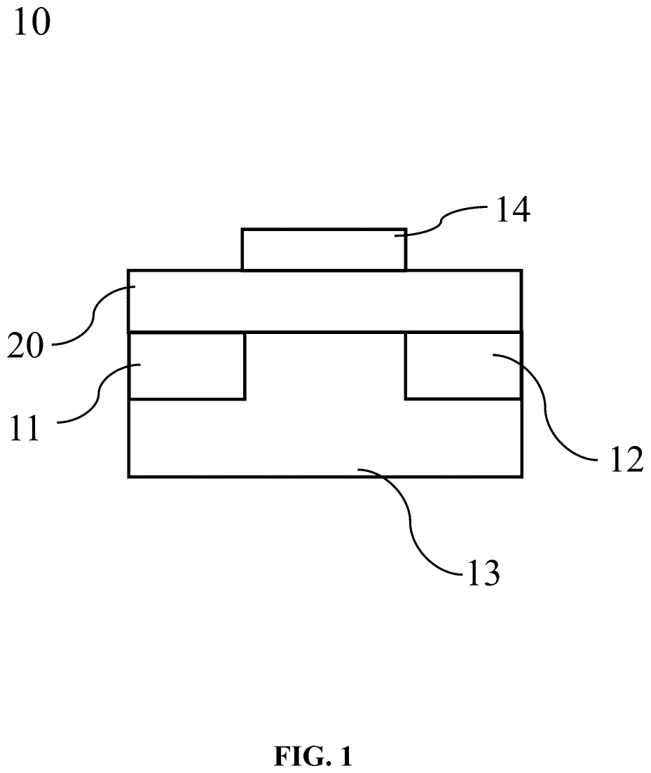

Please refer to FIG. 1. As shown in FIG. 1, the transistor 10 includes a source 11, a drain 12, a body 13, a gate 14 and an oxide layer 20. The source 11, drain 12, body 13 and gate 14 are configured in the transistor 10. The oxide layer 20 connects to the source 11, drain 12, body 13 and gate 14. The transistor 10 of the present embodiment is a P-type semiconductor component or an N-type semiconductor component. The transistor 10 of the present embodiment is Field Effect Transistor (FET). Further, the Field Effect Transistor (FET) is Metal Oxide Semiconductor Field Effect Transistor (MOSFET). The Metal Oxide Semiconductor Field Effect Transistor (MOSFET) of the present embodiment is N-type Metal Oxide Semiconductor Field Effect Transistor (NMOSFET) or P-type Metal Oxide Semiconductor Field Effect Transistor (PMOSFET).

The oxide layer 20 is a dielectric constant material. The dielectric constant material with the dielectric constant which is larger than or equal to 3.9 can be used as the dielectric constant material of the present embodiment. The oxide layer 20 is an insulator. The dielectric constant materials of the present embodiment are Silicon Dioxide (SiO₂), Silicon Nitride (SiN₄), Hafnium (IV) Oxide (HfO₂), Aluminum Oxide (Al₂O₃), Nitrogen Pentoxide (Ta₂O₅) or Titanium Dioxide (TiO₂). The thickness of the dielectric constant material ranges from 5 nanometer (nm) to 150 nanometer (nm).

The transistor 10 of the present embodiment is P-type Metal Oxide Semiconductor Field Effect Transistor (PMOSFET). The structure of P-type Metal Oxide Semiconductor Field Effect Transistor (PMOSFET) is N-type semiconductor substrate, and N-type semiconductor substrate is regarded as the body 13. The both sides of N-type semiconductor substrate are the source 11 and the drain 12. The source 11 and the drain 12 have high density hole. The distance between the source 11 and the drain 12 forms a channel length. The oxide layer 20 is configured on the source 11 and the drain 12. A metal layer or Poly-Silicon is configured on the oxide layer 20, and the metal layer or Poly-Silicon is regarded as the gate 14. The oxide layer 20 is configured on the N-type semiconductor substrate, and the metal layer or the Poly-Silicon which is configured on the oxide layer 20 forms a capacitance. The thickness of the oxide layer 20 and dielectric constant of the oxide layer 20 are used to calculate capacitance value.

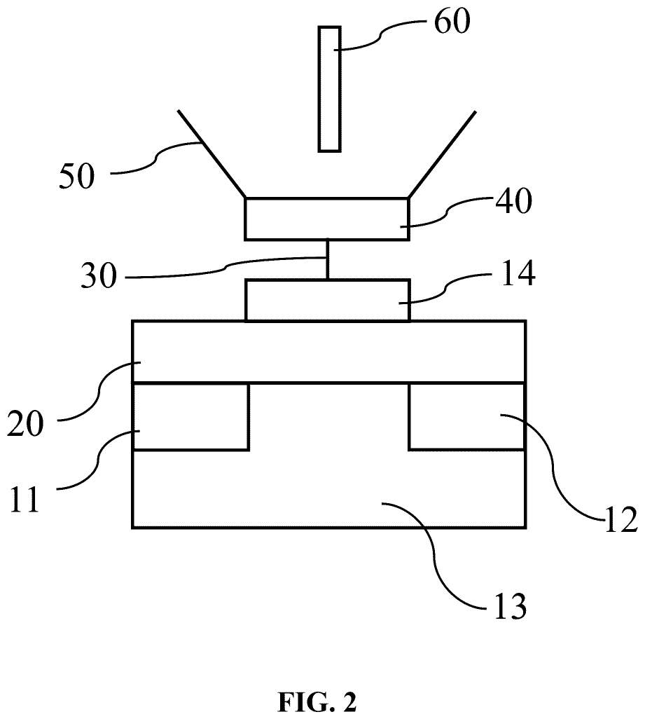

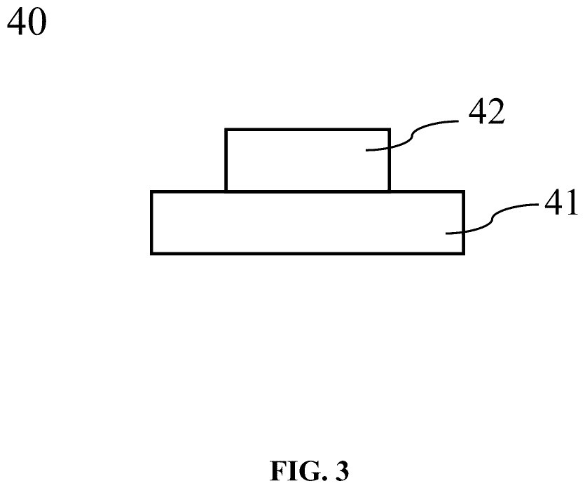

Please refer to FIG. 2 and FIG. 3. An extended gate 40 connects to the gate 14. The extended gate 40 includes a substrate 41 and a sensing layer 42. The substrate 41 of the present embodiment is Indium Tin Oxide (ITO) conductive glass. Specifically, the gate 14 of the embodiment connects to the extended gate 40 via a metal conductive wire 30, and the surface of the substrate 41 of the extended gate 40 has sensing layer 42. The metal conductive wire 30 is Aluminum metal conductive wire. The sensing layer 42 is a sensing material. The sensing material is resistance material or capacitance material which is/are film-shaped. The resistance material is Titanium Nitride (TiN), Zirconium Nitride (ZrN), Niobium Nitride (NbN) or Hafnium Nitride (HfN). The capacitance material is Hafnium (IV) Oxide (HfO₂), Zirconium Dioxide (ZrO₂), Niobium (V) Oxide (NbOₓ) or Titanium Dioxide (TiO₂). The resistance value of resistance material is less than 500,000 ohms (Ω), and the capacitance value of the capacitance material is larger than 1 nanofarads (nF). The sensing material of the present embodiment is Titanium Nitride (TiN). A user uses sputtering to form the sensing layer 42 on the substrate 41 of the extended gate 40, the sensing material of sensing layer 42 is Titanium Nitride (TiN). Indium Tin Oxide (ITO) conductive glass has sensing material Titanium Nitride (TiN) on surface of the Indium Tin Oxide (ITO) conductive glass, sensing material is sensing area. The use of the sensing area is adjusted according to the actual situation. The diameter of sensing area ranges from 10 micrometers (μm) to 10 millimeters (mm), and the sensing area of the present embodiment is a circle with diameter of 3 millimeter (mm). Only the sensing area of the extended gate 40 contacts the test solution, and the rest of the extended gate 40 except the sensing area is sealed with epoxy resin to create insulation.

Please refer to FIG. 2. The tank 50 connects to the extended gate 40. Specifically, the tank 50 is fixed on the extended gate 40, and connection between the tank 50 and the extended gate 40 is sealed with epoxy resin. Therefore, the tank 50 achieves sealing effect when the test solution is deposed therein. The tank 50 remains its bottom empty, thus the sensing material of sensing layer 42 contacts the test solution.

Please refer to FIG. 2. The reference electrode 60 is deposed in the tank 50. The reference electrode 60 is a standard reference electrode. The reference electrode 60 is Silver/Silver Chloride (Ag/AgCl) reference electrode or Calomel electrode. The reference electrode 60 of the present embodiment is Silver/Silver Chloride (Ag/AgCl) reference electrode. The concentration and volume of Potassium Chloride (KCl) in the electrode column of the Silver/Silver Chloride (Ag/AgCl) reference electrode is fixed to maintain the reference potential of Silver/Silver Chloride (Ag/AgCl) reference electrode. The user fixes a distance between the sensing area of the extended gate 40 and the reference electrode 60, thus to let the reference electrode 60 provide the stable relative electric potential. The distance between the sensing area of the extended gate 40 and the reference electrode 60 ranges from 10 micrometers (μm) to 50 millimeters (mm).

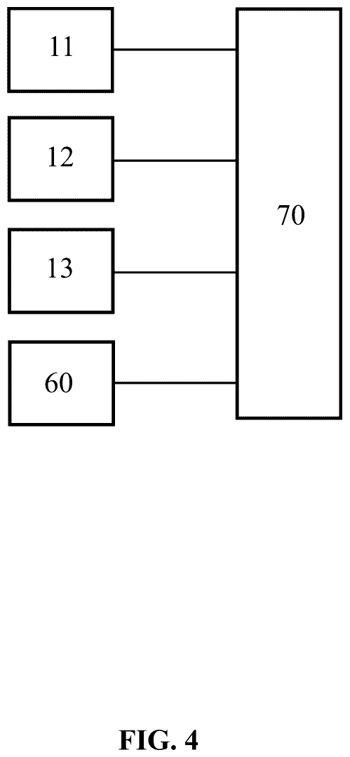

Please refer to FIG. 4. The analysis device 70 connects to the source 11, the drain 12, the body 13 and the reference electrode 60. Further, the analysis device 70 connects to the source 11, drain 12, body 13 and reference electrode 60 via conductive wire respectively. On the other hand, please refer to FIG. 2 and FIG. 4 simultaneously. In the present embodiment, the source 11, the drain 12, the body 13 and the gate 14 are configured in the transistor 10, and the gate 14 connects to the extended gate 40. Therefore, the analysis device 70 of the present embodiment is able to detect the electric signal of the gate 14, the extended gate 40 or combinations thereof via the connections therein the transistor 10 and the connection therebetween the gate 14 and extended gate 40. The conductive wire is conductive metal material. The analysis device 70 is a semiconductor device analyzer. The semiconductor device analyzer measures the current between the drain 12 and the source 11 for different pH test solution, and the voltage and current are acquired to make a chart, therefore to further obtain a curved graph of different pH test solution. Specifically, the semiconductor device analyzer which represents the equivalent functions and no matter what brand it is that can be used therein. The brand of the semiconductor device analyzer of the present embodiment is Keysight, and the model per se is B1500A. Moreover, the current from the drain 12 to the source 11 is fixed. The current corresponding to the variable voltage and pH of the test solution are taken to make a graph, thus the pH sensitivity is able to be calculated.

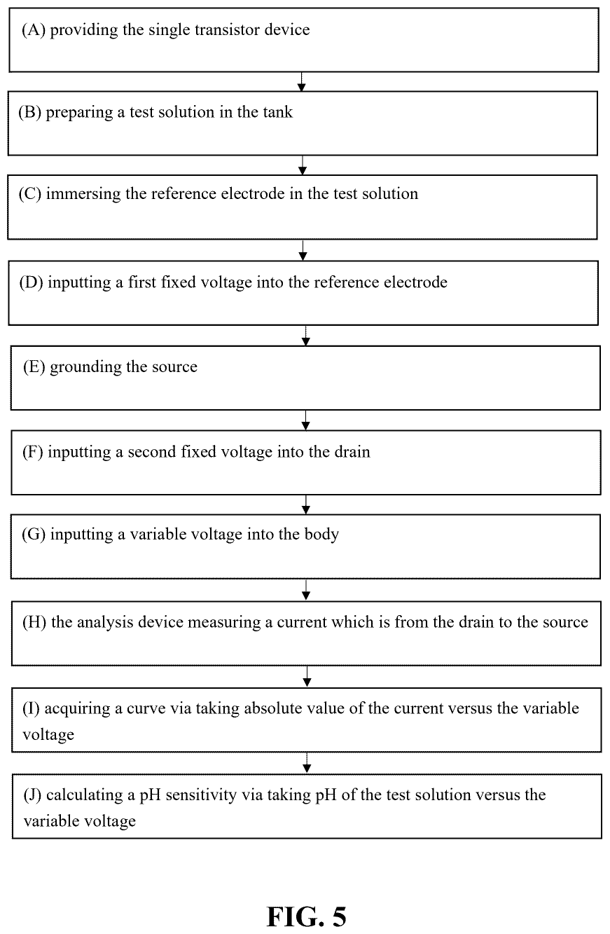

Please refer to FIG. 5, an operating method of the single transistor sensing device of the present embodiment. First, the step (A) is providing the single transistor sensing device. The step (B) is preparing a test solution in the tank 50. The analysis device 70 connects to the source 11, drain 12, body 13 and reference electrode 60 via conductive wire respectively. The test solution is a buffer solution. The temperature of the test solution is fixed, and the temperature is general room temperature. The pH of the test solution ranges from 4 to 10.

The step (C) is immersing the reference electrode 60 in the test solution. The distance between the sensing area of the extended gate 40 and the reference electrode 60 of the present embodiment is 1 millimeter (mm). The step (D) is inputting a first fixed voltage into the reference electrode 60. When the transistor 10 is P-type Metal Oxide Semiconductor Field Effect Transistor (PMOSFET), the first fixed voltage is from −0.3 volt to −3.3 volt. When the transistor 10 is N-type Metal Oxide Semiconductor Field Effect Transistor (NMOSFET), the first fixed voltage ranges from 0.3 volt to 3.3 volt.

The step (E) is grounding the source 11. The source 11 of the present embodiment is grounded, but the source 11 do not connect to the body 13. The step (F) is inputting a second fixed voltage into the drain 12. When the transistor 10 is P-type Metal Oxide Semiconductor Field Effect Transistor (PMOSFET), the second fixed voltage ranges from −100 millivolt to −2,000 millivolt. When the transistor 10 is N-type Metal Oxide Semiconductor Field Effect Transistor (NMOSFET), the second fixed voltage ranges from 100 millivolt to 2,000 millivolt. The step (G) is inputting a variable voltage into the body 13. When the transistor 10 is P-type Metal Oxide Semiconductor Field Effect Transistor (PMOSFET), the variable voltage ranges from 0 volt to 15 volt. When the transistor 10 is N-type Metal Oxide Semiconductor Field Effect Transistor (NMOSFET), the variable voltage ranges from 0 volt to −15 volt.

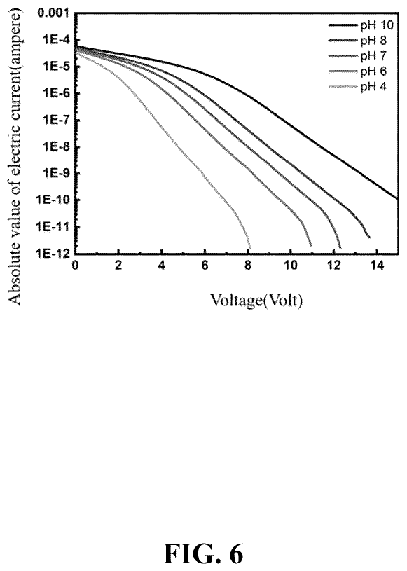

Moreover, the step (H) is the analysis device 70 measuring current which is from the drain 12 to the source 11. The step (I) is acquiring a curve via taking absolute value of current versus the variable voltage. Specifically, the present embodiment is replacing the test solution with test solution of different pH values, and obtaining a curve graph of the change voltage versus the absolute value of the current according to each test solution of different pH value. The test solution can be measured starting from pH of 4 to pH of 10, or the test solution can be alternatively measured starting from pH of 10 to pH of 4 respectively. Please refer to FIG. 6. The analysis device 70 converts the current from the drain 12 to the source 11 to absolute value, and takes the absolute value of the current. The analysis device 70 plots a graph to acquire a curved graph via the absolute value of the current corresponding to the variable voltage of each test solution with different pH value. Therefore, the source 11 is grounded. The user inputs the first fixed voltage, and the user inputs the second fixed voltage into the reference electrode 60. The first fixed voltage and the second fixed voltage are fixed, and the channel of P-type Metal Oxide Semiconductor Field Effect Transistor (PMOSFET) or the channel of N-type Metal Oxide Semiconductor Field Effect Transistor (NMOSFET) is opened. The user inputs the variable voltage into the body 13, and the channel of the transistor 10 is closed gradually. The body effect closes the channel of the transistor 10 gradually to make high subthreshold swing. Therefore, the single transistor sensing device which is operated under the operating method of the present embodiment can acquire the pH sensitivity which is larger than the ideal Nernst value 59.6 mV/pH.

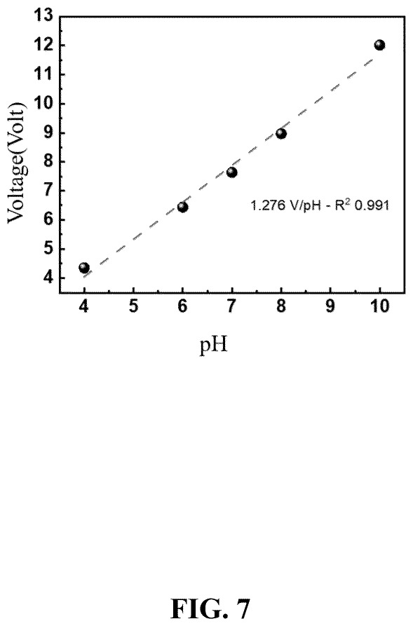

Please refer to FIG. 6. The step (J) is calculating a pH sensitivity via taking pH of the test solution versus the variable voltage. The analysis device 70 plots a graph to acquire a curved graph via the absolute value of current corresponding to the variable voltage. Further, the analysis device 70 plots a graph to calculate the pH sensitivity and linear value via fixing the current which is from the drain 12 to the source 11 and variable voltage corresponding to pH of the test solution. Please refer to FIG. 7. Specifically, the transistor 10 of the present embodiment is P-type Metal Oxide Semiconductor Field Effect Transistor (PMOSFET). The user inputs the first fixed voltage which is −2 Volt into the reference electrode 60, and the user inputs the second fixed voltage which is −300 millivolt into the drain 12. The absolute value of current from the drain 12 to the source 11 is 10 nanoampere, which is regarded as a baseline. The analysis device 70 plots a graph to calculate the pH sensitivity which is 1,276 mV/pH via the linear regression according to the variable voltage versus the pH of the test solution which corresponds to the baseline. The pH sensitivity is greater than the Nernst value 59.6 mV/pH, and the linear value is 0.991. Specifically, the user adjusts the first fixed voltage which is input into the reference electrode 60, and the second fixed voltage which is input into the drain 12, and the user inputs the variable voltage into the body 13 to acquire pH sensitivity according to the single transistor sensing device and operating method of the present embodiment. The pH sensitivity is 3 to 30 times greater than the ideal Nernst value which is 59.6 mV/pH.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure. While the preferred embodiment of the invention has been illustrated and described, it will be appreciated that various changes can be made therein without departing from the spirit and scope of the invention.

What is claimed is:

1. A single transistor sensing device, comprising:
a transistor;
wherein the transistor comprises:
a source, configured in the transistor;
a drain, configured in the transistor;
a body, configured in the transistor;
a gate, configured in the transistor;
an oxide layer, connected to the source, the drain, the body and the gate;
an extended gate, connected to the gate;
wherein the extended gate comprises:
a substrate;
a sensing layer, connecting to the substrate;
a tank, connected to the extended gate;
a reference electrode, deposed in the tank; and
an analysis device, connected to the source, the drain, the body and the reference electrode.

2. The single transistor sensing device as claimed in claim 1, the transistor is P-type Metal Oxide Semiconductor Field Effect Transistor (PMOSFET) or N-type Metal Oxide Semiconductor Field Effect Transistor (NMOSFET).

3. The single transistor sensing device as claimed in claim 1, the oxide layer is dielectric constant material.

4. The single transistor sensing device as claimed in claim 1, the sensing layer is resistance material or capacitance material.

5. The single transistor sensing device as claimed in claim 4, resistance value of the resistance material is less than 500,000 ohms (Ω).

6. The single transistor sensing device as claimed in claim capacitance value of capacitance material is larger than 1 nanofarads (nF).

7. An operating method of a single transistor sensing device, comprising the following steps:
(A) providing the single transistor sensing device as claimed in the claim 1;
(B) preparing a test solution in the tank;
(C) immersing the reference electrode in the test solution;
(D) inputting a first fixed voltage into the reference electrode;
(E) grounding the source;
(F) inputting a second fixed voltage into the drain;
(G) inputting a variable voltage into the body;
(H) the analysis device measuring a current which is from the drain to the source;
(I) acquiring a curve via taking absolute value of the current versus the variable voltage; and
(J) calculating a pH sensitivity via taking pH of the test solution versus the variable voltage.

8. The operating method of the single transistor sensing device as claimed in claim 7, pH of the test solution ranges from 4 to 10.

9. The operating method of the single transistor sensing device as claimed in claim 7, when the single transistor sensing device is P-type Metal Oxide Semiconductor Field Effect Transistor (PMOSFET), the first fixed voltage ranges from −0.3 volt to −3.3volt.

10. The operating method of the single transistor sensing device as claimed in claim 7, when the single transistor sensing device is N-type Metal Oxide Semiconductor Field Effect Transistor (NMOSFET), the first fixed voltage ranges from 0.3 volt to 3.3 volt.

11. The operating method of the single transistor sensing device as claimed in claim 7, when the single transistor sensing device is P-type Metal Oxide Semiconductor Field Effect Transistor (PMOSFET), the second fixed voltage ranges from −100 millivolt to −2.000 millivolt.

12. The operating method of the single transistor sensing device as claimed in claim 7, when the single transistor sensing device is N-type Metal Oxide Semiconductor Field Effect Transistor (NMOSFET), the second fixed voltage ranges from 100 millivolt to 2,000 millivolt.
